(19) United States
(12) Patent Application Publication
(10) Pub. No.: US 2025/0132240 A1
(43) Pub. Date: Apr. 24, 2025

(54) PACKAGE WITH BACK-TO-BACK DIE STACKING

(71) Applicant: Micron Technology, Inc., Boise, ID (US)

(72) Inventors: Faxing CHE, Singapore (SG); Hong Wan NG, Singapore (SG)

(21) Appl. No.: 18/781,338

(22) Filed: Jul. 23, 2024

Related U.S. Application Data
(60) Provisional application No. 63/591,322, filed on Oct. 18, 2023.

(51) Int. Cl. H01L 23/498; H01L 21/48; H01L 21/56; H01L 23/00; H01L 23/31; H01L 25/065; H10B 80/00

(52) U.S. Cl. CPC H01L 23/49833; H01L 21/4853; H01L 21/565; H01L 23/3107; H01L 24/16; H01L 24/32; H01L 24/73; H01L 24/81; H01L 24/96; H01L 24/97; H01L 25/0652; H10B 80/00; H01L 23/49811; H01L 24/13; H01L 2224/1357; H01L 2224/16238; H01L 2224/32145; H01L 2224/73253; H01L 2224/81203; H01L 2224/81815; H01L 2224/96; H01L 2224/97; H01L 2924/1436; H01L 2924/15153; H01L 2924/15174; H01L 2924/3511

(57) ABSTRACT

Implementations described herein relate to various semiconductor device assemblies. In some implementations, semiconductor device assembly includes a first redistribution layer and a second redistribution layer, a first semiconductor die disposed between the first redistribution layer and the second redistribution layer and connected to the first redistribution layer, and a second semiconductor die disposed between the first redistribution layer and the second redistribution layer and connected to the second redistribution layer. The first semiconductor die may have an active surface and a back surface opposite the active surface of the first semiconductor die. The second semiconductor die may have an active surface and a back surface opposite the active surface of the second semiconductor die. The second semiconductor die may be stacked on the first semiconductor die with the back surface of the second semiconductor die facing the back surface of the first semiconductor die.

### CROSS REFERENCE TO RELATED APPLICATION

This patent application claims priority to U.S. Provisional Patent Application No. 63/591,322, filed on Oct. 18, 2023, and entitled “PACKAGE WITH BACK-TO-BACK DIE STACKING,” The disclosure of the prior application is considered part of and is incorporated by reference into this patent application.

### TECHNICAL FIELD

The present disclosure generally relates to semiconductor devices and methods of forming semiconductor devices. For example, the present disclosure relates to a package with back-to-back die stacking.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus that includes back-to-back stacked semiconductor dies.

FIGS. 4A-4D are diagrams illustrating an example associated with manufacturing an apparatus using a fan-out packaging (FOP) technology.

FIG. 5 is a flowchart of an example method of forming an integrated assembly or memory device having a package with back-to-back die stacking.

### DETAILED DESCRIPTION

Memory devices capable of high performance, high capacity, and high bandwidth are useful in applications relating to artificial intelligence (AI), data centers, and/or cloud computing, among other examples. Memory devices and similar components may include one or more semiconductor packages, also referred to as semiconductor device assemblies. At a high level, a semiconductor package may include one or more semiconductor devices, such as ICs or similar components. A semiconductor device may include one or more semiconductor dies (e.g., in a stacked arrangement) electrically coupled to a substrate, such as an organic substrate (e.g., a printed circuit board (PCB)). Use of an organic substrate may affect a capacity, a thickness, and/or a bandwidth of the package. For example, stacking various components on an organic substrate may result in large packages (e.g., packages with a relatively large profile and/or height).

Some implementations described herein use FOP technology to reduce package profile, improve package integration and throughput, reduce package defects associated with use of an organic substrate, reduce package cost due to organic-substrate elimination, or to achieve similar benefits. For example, stacking semiconductor dies in a package, in connection with FOP technology, increases memory bandwidth and/or capacity. In some implementations, a package using an FOP technology may eliminate an organic substrate, thereby reducing a thickness of the package and improving heat dissipation.

However, generally, a package using an FOP technology may include a stack of semiconductor dies that uses separate molding layers for each level of the stack. For example, the package may include a first level including a first redistribution layer and one or more first dies disposed on the first redistribution layer and surrounded by a mold compound, and a second level, on the first level, including a second redistribution layer and one or more second dies disposed on the second redistribution layer and surrounded by a mold compound. This configuration increases package thickness, limits thermal dissipation, increases manufacturing process steps (e.g., associated with multiple molding steps), and/or is prone to warpage during manufacturing (e.g., due to lacking vertical symmetry).

In implementations described herein, a package using an FOP technology may include a stack of semiconductor dies in a back-to-back configuration. For example, a first semiconductor die and a second semiconductor die may be stacked (e.g., using a die attach film) with a back surface of the second semiconductor die facing the back surface of the first semiconductor die. This configuration reduces package thickness, and improves integration and performance for high-capacity, high-speed, and high-bandwidth applications. Furthermore, in the back-to-back configuration, active surfaces of the semiconductor dies face an exterior of the package (e.g., face respective redistribution layers), thereby improving thermal dissipation by locating the active surfaces of the dies closer to the package exterior and improving an electrical performance of the package by reducing the length of electrical connections between the dies and the redistribution layers. Moreover, the back-to-back configuration provides vertical symmetry to the package that aids in controlling wafer and package warpage (e.g., process-induced warpage) during wafer and package assembly processing. Additionally, manufacturing the package using an FOP technology may be performed on a stiff carrier at the wafer and/or panel level, thereby eliminating an organic substrate and providing additional warpage control.

In some implementations, interconnects (e.g., microbumps) of the first semiconductor die may connect to the first redistribution layer via solder joints, whereas interconnects (e.g., microbumps) of the second semiconductor die may directly connect to the second redistribution layer free of solder joints. Accordingly, a solder reflow process or a thermal compression bonding (TCB) process used for bonding the first semiconductor die (e.g., at a wafer level) may be eliminated for the second semiconductor die, such that fewer manufacturing processing steps are needed and less material is used (e.g., by eliminating solder caps for the interconnects of the second semiconductor die). Furthermore, the back-to-back configuration allows encapsulation of the semiconductor dies to be performed in a single compression molding process (e.g., at a wafer level), such that fewer manufacturing processing steps are needed. Moreover, the back-to-back configuration facilitates using a single wafer bonding/de-bonding process (e.g., a single carrier support system may be used from beginning to end of the manufacturing process), such that fewer manufacturing processing steps are needed. Accordingly, the package can be manufactured in a cost-effective manner with high throughput.

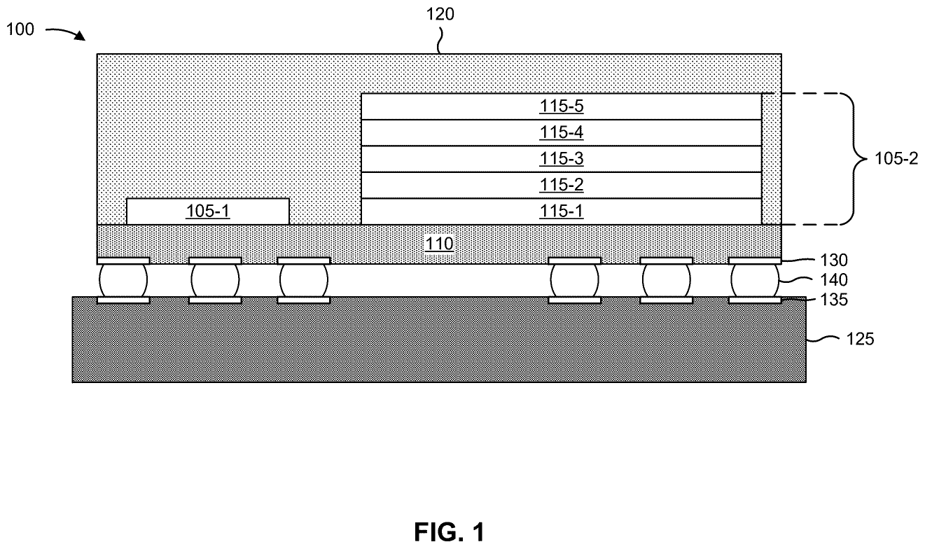

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

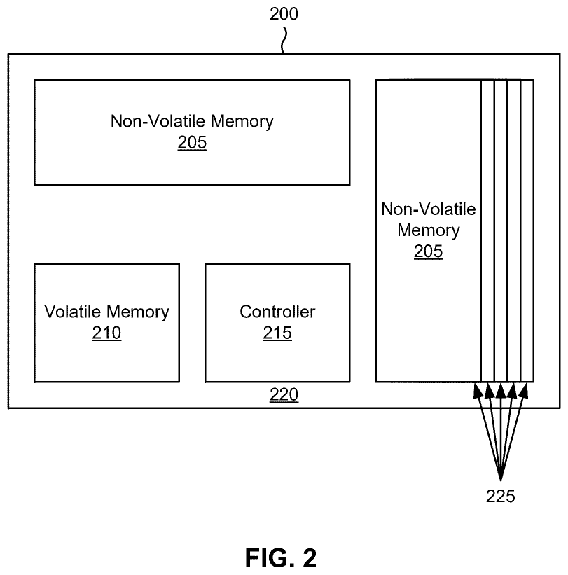

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (cMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

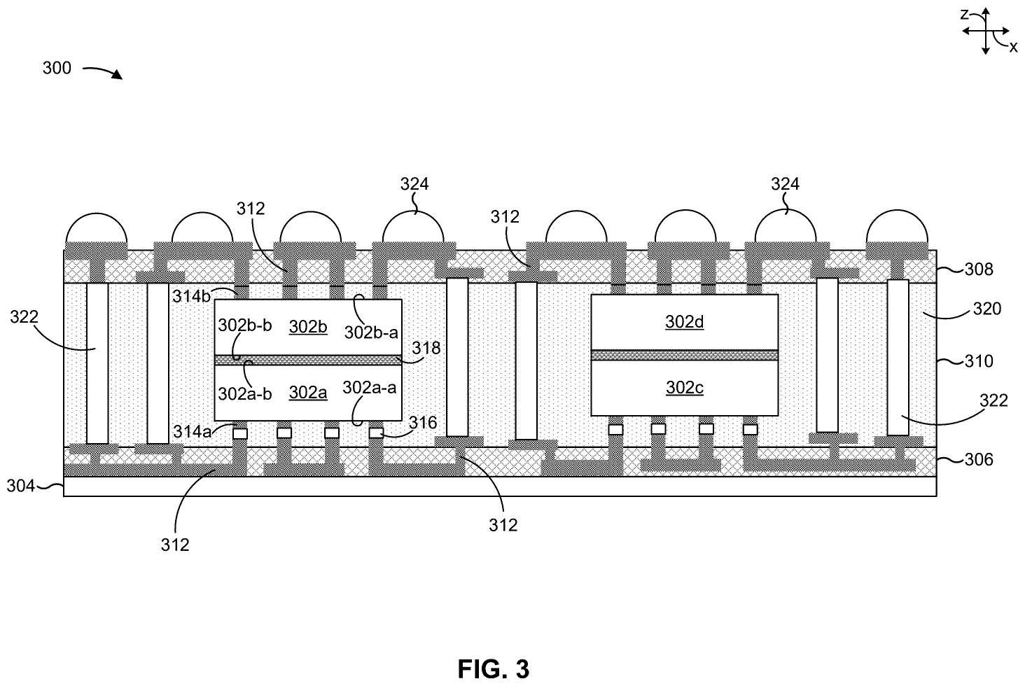

FIG. 3 is a diagram of an example apparatus 300 that includes back-to-back stacked semiconductor dies. The apparatus 300 may include any type of device that includes ICs. For example, the apparatus 300 may include a memory device, a flash memory device, a NAND memory device, a NOR memory device, a RAM memory device, a ROM memory device, a DRAM device, an SRAM device, a holographic RAM (HRAM) device, a synchronous dynamic RAM (SDRAM) device, a ferroelectric RAM (FeRAM) device, a magnetic RAM (MRAM) device, a resistive RAM (RRAM) device, an SSD, a microchip, and/or an SoC. In some implementations, the apparatus 300 may be a memory device, or a similar semiconductor device, suitable for high-density, high-speed, and high-bandwidth applications. For example, the apparatus 300 may be a graphics DRAM device (e.g., a graphics double data rate (GDDR) device).

In some implementations, the apparatus 300 may be manufactured using an FOP technology. “FOP” may refer to a packaging process associated with connections (e.g., I/O connections or other electrical connections) “fanned-out” from a chip surface (e.g., via a redistribution layer (RDL)), thereby enabling more external I/O connections than are provided on organic-substrate-based packages, such as the semiconductor packages described above in connection with FIGS. 1 and 2. Additionally, or alternatively, FOP may refer to using a mold compound (e.g., an epoxy mold compound) to fully embed one or more dies (e.g., memory dies or similar dies) of a semiconductor device, rather than attaching one or more dies on a substrate or an interposer. FOP may be referred to as a wafer-level packaging (WLP) technology.

The apparatus 300 may be, or may include, a semiconductor device assembly, as described herein. The apparatus 300 may include a plurality of semiconductor dies 302 (shown as 302a, 302b, 302c, and 302d). A semiconductor die 302 may include a DRAM IC die, such as a GDDR IC die. The semiconductor dies 302 may be copies of each other. As shown in FIG. 3, the apparatus 300 may include a first semiconductor die 302a, and a second semiconductor die 302b in a stacked arrangement with the first semiconductor die 302a. For example, the first semiconductor die 302a and the second semiconductor die 302b may define a back-to-back die stack (e.g., the first semiconductor die 302a and the second semiconductor die 302b may be stacked back-to-back), as described herein.

In some implementations, the apparatus 300 may include a substrate 304 (e.g., a semiconductor, such as silicon, layer, a protective layer, or the like). The apparatus 300 may include a first RDL 306 (e.g., a back side RDL) and a second RDL 308 (e.g., a front side, or active side, RDL). The first RDL 306 may be disposed on the substrate 304. The first RDL 306 and the second RDL 308 may be separated by a molding layer 310.

The first RDL 306 and/or the second RDL 308 may each be a single-layer RDL or a multilayer RDL. The first RDL 306 and/or the second RDL 308 may include a dielectric material (e.g., polyimide or SiO₂, among other examples) and one or more electrical connections 312, such as conductive (e.g., copper) traces, pads, or the like, used to electrically couple the RDLs 306, 308 to various components of the apparatus 300, and/or to electrically couple the apparatus 300 to other components (e.g., a printed circuit board (PCB) or a similar structure). In some implementations, the first RDL 306 and/or the second RDL 308 may redistribute I/O pads for one or more of the semiconductor dies 302 to other locations of the apparatus 300, such as for providing better access to bond pads or the like when electrically coupling the apparatus 300 to another component (e.g., a PCB).

As shown in FIG. 3, the first RDL 306 may be disposed, in a z-axis direction, on a first side of the semiconductor dies 302, and the second RDL 308 may disposed, in the z-axis direction, on an opposing second side of the semiconductor dies 302. In other words, the first semiconductor die 302a and the second semiconductor die 302b may be disposed between the first RDL 306 and the second RDL 308. The first semiconductor die 302a may be disposed on the first RDL 306. For example, the first semiconductor die 302a may be connected (e.g., mechanically and electrically connected) to the first RDL 306. The second semiconductor die 302b may be disposed on the second RDL 308. For example, the second semiconductor die 302b may be connected (e.g., mechanically and electrically connected) to the second RDL 308.

The first semiconductor die 302a has an active surface 302a-a and a back surface 302a-b opposite the active surface 302a-a. Similarly, the second semiconductor die 302b has an active surface 302b-a and a back surface 302b-b opposite the active surface 302b-a. An active surface of a semiconductor die 302 may be electrically active (e.g., a surface having one or more electrical connections and at which electrical signals are input and/or output), and a back surface of the semiconductor die 302 may be electrically inactive. For example, the active surface 302a-a of the first semiconductor die 302a may have one or more interconnects 314a (e.g., a plurality of interconnects 314a). Similarly, the active surface 302b-a of the second semiconductor die 302b may have one or more interconnects 314b (e.g., a plurality of interconnects 314b). The interconnects 314a, 314b may include electrically-conductive bumps, such as microbumps, solder bumps, pillars, or the like. The interconnects 314a, 314b may be used to electrically connect the semiconductor dies 302 to other components of the apparatus 300 (e.g., the RDLs 306, 308) via bump bonding (e.g., direct chip attachment (DCA)) or the like.

The interconnects 314a of the first semiconductor die 302a may connect to electrical connections 312 of the first RDL 306 via solder joints 316 (e.g., prior to assembly of the apparatus 300, the interconnects 314a of the first semiconductor die 302a may have solder caps). The interconnects 314b of the second semiconductor die 302b may directly connect to electrical connections 312 of the second RDL 308 free of solder joints (e.g., prior to assembly of the apparatus 300, the interconnects 314b of the second semiconductor die 302b may not have solder caps). However, in some implementations, the interconnects 314b of the second semiconductor die 302b may connect to electrical connections 312 of the second RDL 308 via solder joints, in a similar manner as described above.

The second semiconductor die 302b may be stacked on the first semiconductor die 302a with the back surface 302b-b of the second semiconductor die 302b facing the back surface 302a-b of the first semiconductor die 302a (e.g., the first semiconductor die 302a and the second semiconductor die 302b define a back-to-back die stack). As described herein, the back-to-back stacking of the first semiconductor die 302a and the second semiconductor die 302b reduces package thickness and shortens electrical interconnections for improved electrical performance. In the back-to-back configuration, the active surface 302a-a of the first semiconductor die 302a faces the first redistribution layer 306, and the active surface 302b-a of the second semiconductor die 302b faces the second redistribution layer 308. In other words, the active surfaces 302a-a, 302b-a face a package exterior, thereby improving thermal dissipation.

The second semiconductor die 302b may be attached to the first semiconductor die 302a by a die attach film (DAF) 318, or another adhesive, between the first semiconductor die 302a and the second semiconductor die 302b. In some implementations, the first semiconductor die 302a and the second semiconductor die 302b are vertically symmetrical (e.g., about a plane defined by the DAF 318). Moreover, the arrangement of the RDLs 306, 308, the molding layer 310, the first semiconductor die 302a, and the second semiconductor die 302b may be vertically symmetrical (e.g., irrespective of electrical connections thereof). As described herein, this vertical symmetry reduces wafer-level and package-level warpage during manufacturing.

The molding layer 310 may include a mold compound 320 (e.g., between the first RDL 306 and the second RDL 308) surrounding the semiconductor dies 302. For example, the semiconductor dies 302 may be disposed in the molding layer 310. The mold compound 320 may be an epoxy mold compound or similar compound suitable for use in semiconductor packaging technology. In some implementations, the mold compound 320 may be a moldable underfill (MUF) material. In that regard, the mold compound 320 (e.g., the MUF material) may surround the interconnects 314a, 314b (e.g., the microbumps).

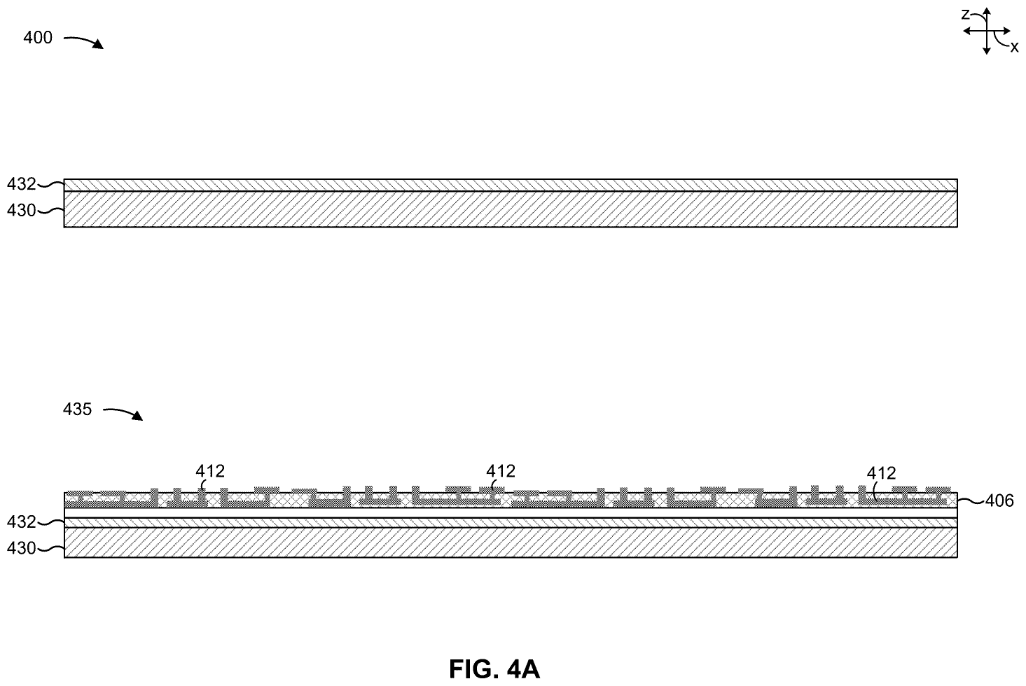

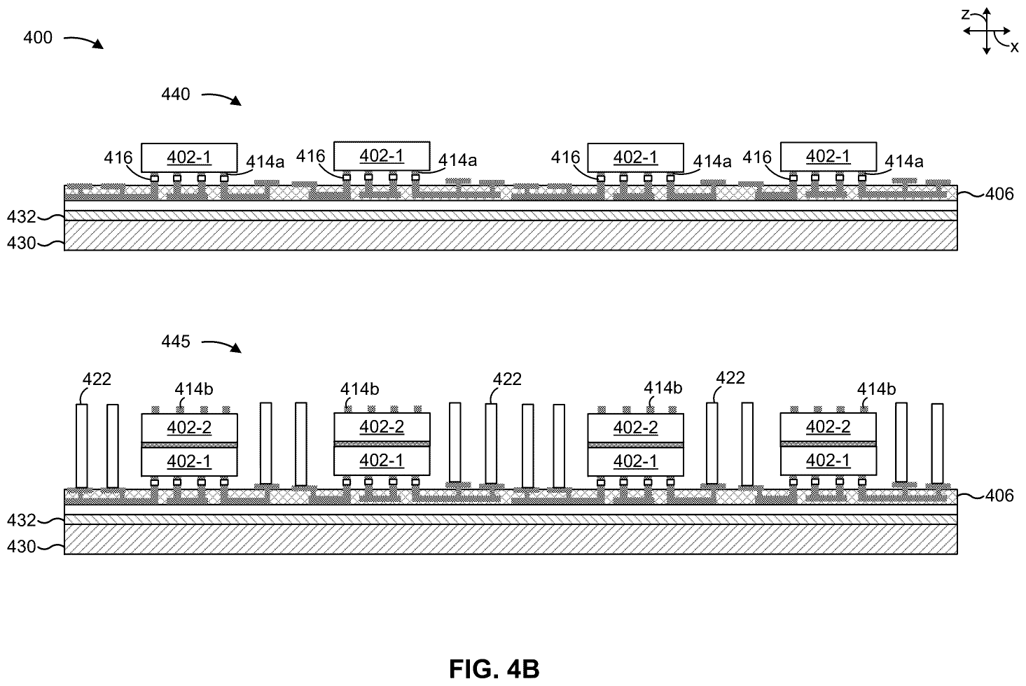

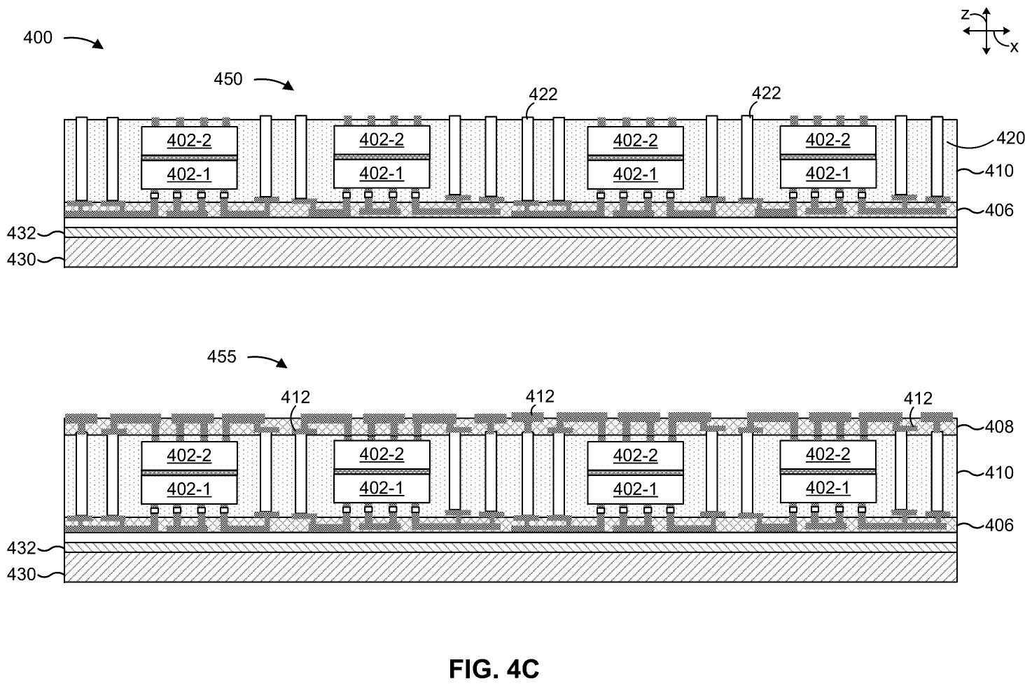

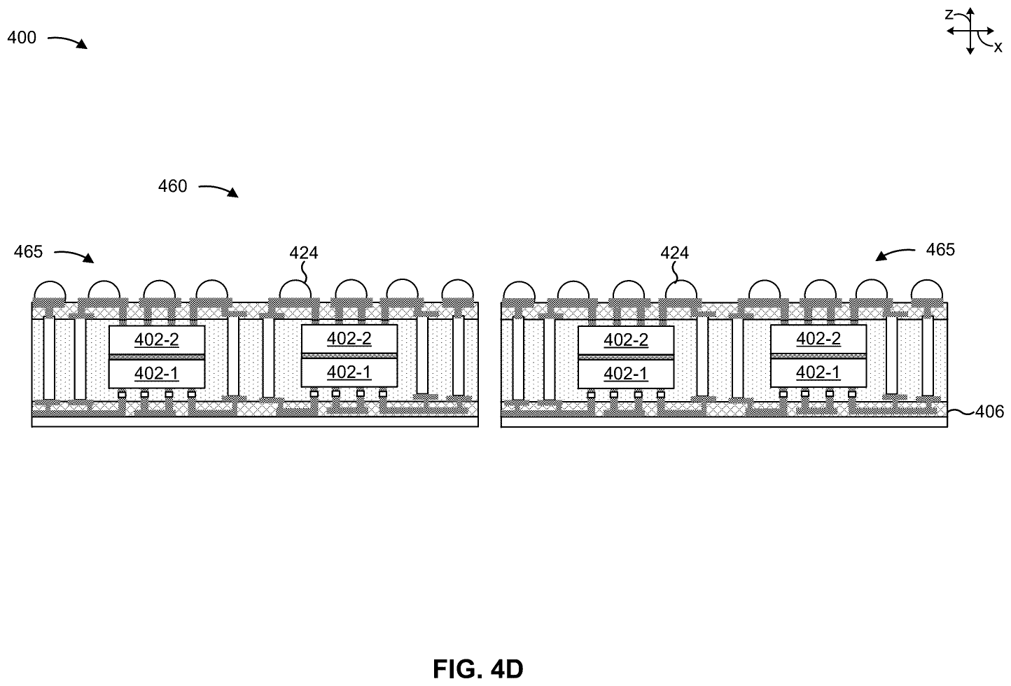

In some implementations, the apparatus 300 may include one or more through-mold interconnects (TMIs) 322, also referred to as through-mold vias (TMVs), extending through the molding layer 310 (e.g., the mold compound 320 may surround the TMIs 322). The TMIs 322 may be used to electrically connect two components of the apparatus 300 to one another. For example, the TMIs 322 may electrically connect the first RDL 306 to the second RDL 308. As described further in connection with FIG. 4B, the TMIs 322 may be associated with vertical wire bonds, metal (e.g., copper) pillar plating, or a similar conductive structure.

The apparatus 300 may include one or more external contacts for electrically connecting the apparatus 300 to one or more other components, such as a PCB or similar structure. For example, the apparatus 300 may include a plurality of solder balls 324 used to electrically couple the apparatus 300 to a PCB or other structure. As an example, the solder balls 324 may be electrically connected to the second RDL 308 (e.g., to pads formed at an exterior surface of the second RDL 308). In some implementations, the apparatus 300 may be manufactured using an FOP technology (e.g., which can eliminate the use of an organic substrate), and thus may be referred to as an FOP apparatus, an FOP semiconductor device assembly, an FOP package, or the like. Additional details regarding an FOP process used to manufacture a semiconductor package, such as the apparatus 300 shown in FIG. 3, are described in connection with FIGS. 4A-4D.

In some implementations, the apparatus 300 may include one or more additional back-to-back die stacks in a similar manner as described above. For example, as shown in FIG. 3, the first semiconductor die 302a and the second semiconductor die 302b may define a first back-to-back die stack, and the apparatus 300 may include (e.g., disposed between the first RDL 306 and the second RDL 308, in a similar manner as described above) a third semiconductor die 302c, and a fourth semiconductor die 302d in a stacked arrangement with the third semiconductor die 302c, that define a second back-to-back die stack. The first semiconductor die 302a and the third semiconductor die 302c may be referred to herein as a first set or batch of dies of the apparatus 300 (e.g., because these dies may be attached to the apparatus 300 as part of a same manufacturing step, as described further in connection with FIG. 4B), and the second semiconductor die 302b and the fourth semiconductor die 302d may be referred to herein as a second set or batch of dies of the apparatus 300 (e.g., because these dies may be attached to the apparatus 300 as part of a same manufacturing step, after the first set of dies are attached, as described further in connection with FIG. 4B). In some implementations, the apparatus 300 may include two semiconductor dies (e.g., a single back-to-back die stack), four semiconductor dies (e.g., two back-to-back die stacks), eight semiconductor dies (e.g., four back-to-back die stacks), or another even number of dies (e.g., that define half as many back-to-back die stacks).

Each of the illustrated x-axis and z-axis is substantially perpendicular to the other axis. Moreover, a y-axis, not shown, is substantially perpendicular to each of the depicted axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIG. 3 is provided as an example. Other examples may differ from what is described with respect to FIG. 3.

FIGS. 4A-4D are diagrams illustrating an example 400 associated with manufacturing an apparatus (e.g., a semiconductor device assembly or a semiconductor package), such as the apparatus 300, using an FOP technology.

As shown in FIG. 4A, the apparatus manufactured using an FOP technology (e.g., the apparatus 300) may be manufactured on a carrier 430. In some implementations, the carrier 430 may be a wafer-shaped carrier, a panel-shaped carrier, or a strip-shaped carrier. The carrier 430 may be constructed from any suitable material used in a semiconductor package manufacturing process. For example, the carrier 430 may be a stiff material that provides control and reduction of wafer warpage during manufacturing of the apparatus. In some implementations, the carrier 430 may be a glass carrier, which may aid in a laser-debonding process, as described further in connection with FIG. 4D. In some implementations, the carrier 430 may be laminated or otherwise coated with a sacrificial layer 432 (e.g., a release layer), also referred to as a release layer. The sacrificial layer 432 may aid during a debonding process (e.g., a laser-debonding process or other debonding process) by permitting the carrier 430 to be easily removed from a package wafer after wafer formation, which is described further in connection with FIG. 4D.

In some implementations, the process used to manufacture the apparatus may be referred to as an RDL-first FOP process, because an RDL is first built on the carrier 430 and/or the sacrificial layer 432, with the remaining components (e.g., dies, mold compounds, or similar components) then built up, in the z-axis direction, on top of the RDL. In this regard, the carrier 430 and/or the sacrificial layer 432 may be prepared for forming an RDL thereon. This may include performing certain RDL preparation steps, such as a dielectric coating process, a dielectric patterning process, a seed layer deposition process, a photoresist coating process, and/or a similar preparation step.

As shown by reference number 435, a first RDL 406 (e.g., RDL 306) may be formed on the carrier 430 and/or the sacrificial layer 432. In some implementations, electrical connections 412 (e.g., electrical connections 312), such as signal traces, bond pads, wire-bond fingers, or similar connections may be integrally formed in the first RDL 406 for purposes of bonding the first RDL 406 to one or more other components of the apparatus, for purposes of bonding the apparatus to one or more external components (e.g., a PCB), and/or for purposes of conducting electricity (e.g., signals) throughout the first RDL 406 and/or throughout the apparatus. In some implementations, forming the first RDL 406 on the carrier 430 and/or the sacrificial layer 432 may include forming a metal (e.g., copper) based RDL and/or forming a metal (e.g., copper) based pad layer. The first RDL 406 may be formed on the carrier 430 and/or the sacrificial layer 432 via a metal (e.g., copper) plating process, a photoresist strip process, a seed layer etching process, and/or another similar process.

As shown by FIG. 4B and as shown by reference number 440, a first set of semiconductor dies 402-1 (e.g., semiconductor die 302a and/or semiconductor die 302c) may be attached and/or bonded to the first RDL 406. In some implementations, the semiconductor dies 402-1 may be attached to the first RDL 406 by forming multiple bonds or joints 416 (e.g., joints 316) between interconnects 414a (e.g., interconnects 314a) of the semiconductor dies 402-1 and the first RDL 406 (e.g., via solder caps of the interconnects 414a). In some implementations, bonding the semiconductor dies 402-1 to the first RDL 406 may include performing a reflow process, a TCB process, and/or a similar process. As described herein, the manufacturing process may include only a single wafer-level and/or panel-level reflow process, thereby simplifying manufacturing (e.g., reducing manufacturing steps and cost) and conserving manufacturing resources (e.g., power, machine time, or the like).

As shown by reference number 445, after the first set of semiconductor dies 402-1 are bonded to the first RDL 406, multiple TMIs 422 (e.g., TMIs 322) may be formed on the first RDL 406. Each TMI 422 may be formed on a respective electrical connection 412 of the first RDL 406, such that each TMI 422 is electrically connected to a respective electrical connection 412. The TMIs 422 may be formed using any suitable technology, such as by vertical wire bonding, metal (e.g., copper) pillar plating, or the like.

In addition, a second set of semiconductor dies 402-2 (e.g., semiconductor die 302b and/or semiconductor die 302d) may be stacked on respective dies 402-1 of the first semiconductor dies 402-1 in a back-to-back configuration. In some implementations, stacking the semiconductor dies 402-2 may include applying DAF to the first set of semiconductor dies 402-1, and applying the second set of semiconductor dies 402-2 (e.g., in a back-to-back configuration) on the DAF. The back-to-back configuration provides package thinning, improved thermal performance, and improved electrical performance, as described herein. The semiconductor dies 402-2 may include interconnects 414b (e.g., interconnects 314b) without solder caps, thereby conserving materials.

As shown in FIG. 4C, and by reference number 450, a compression molding process (sometimes referred to as a wafer-level compression molding process and/or a panel-level compression molding process) may be performed to encapsulate the semiconductor dies 402-1, the semiconductor dies 402-2, and/or the TMIs 422 in a mold compound 420 (e.g., mold compound 320), forming a molding layer 410 (e.g., molding layer 310). For example, forming the molding layer 410 may include compressing the mold compound 420 on the first semiconductor dies 402-1, the second semiconductor dies 402-2, and the first RDL 406. In some implementations, forming the molding layer 410 may include surrounding the first semiconductor dies 402-1, the second semiconductor dies 402-2, and/or the TMIs 422 with the mold compound 420. In some implementations, the mold compound 420 may be an MUF that fills between the interconnects 414a (e.g., microbumps) of the semiconductor dies 402-1 and/or the interconnects 414b (e.g., microbumps) of the semiconductor dies 402-2. In some implementations, additional mold processing steps may be performed (e.g., if the compression molding process resulted in overmolding), such as back-grinding, TMI revealing, and/or interconnect revealing. As described herein, the manufacturing process may include only a single wafer-level and/or panel-level molding process, thereby simplifying manufacturing (e.g., reducing manufacturing steps and cost) and conserving manufacturing resources (e.g., power, machine time, or the like).

As shown by reference number 455, a second RDL 408 (e.g., RDL 308) may be formed on the molding layer 410. The second RDL 408 may be formed in a similar manner as the first RDL 406, as described herein. In some implementations, forming the second RDL 408 may include forming pads for external contacts of the apparatus. In some implementations, electrical connections 412 (e.g., electrical connections 312) of the second RDL 408 may be formed directly on the interconnects 414b of the semiconductor dies 402-2 (e.g., such that solder caps and/or additional bonding processes for the semiconductor dies 402-2 can be eliminated from the manufacturing process).

As shown in FIG. 4D, and by reference number 460, following formation of the second RDL 408, a debonding process (sometimes referred to as a wafer-level debonding process and/or a panel-level debonding process) and/or a solder ball attach process may be performed. More particularly, the carrier 430 and/or the sacrificial layer 432 may be removed from the first RDL 406, resulting in a standalone package wafer and/or panel. For example, in some implementations, the carrier 430 and/or the sacrificial layer 432 may be removed from the standalone package wafer and/or panel via a laser debonding process. In some implementations, the debonding process may include cleaning a bottom (in the z-axis direction) surface of the standalone package wafer and/or panel to remove residual adhesives, portions of the sacrificial layer 432, or similar contaminants. As described herein, due to the back-to-back configuration of the semiconductor dies 402-1, 402-2 the manufacturing process may include only a single wafer-level and/or panel-level bonding and de-bonding, thereby simplifying manufacturing (e.g., reducing manufacturing steps and cost) and conserving manufacturing resources (e.g., power, machine time, or the like).

Moreover, one or more solder balls 424 (e.g., solder balls 324) may be soldered (e.g., attached and reflowed) to the standalone package wafer and/or panel, which may ultimately be used to provide electrical connectivity to a PCB or similar structure. In some implementations, attaching the one or more solder balls 424 to the standalone package wafer and/or panel may be referred to as wafer-level and/or panel level solder ball attachment and reflow.

The standalone package wafer and/or panel may then be singulated into multiple packages 465 (e.g., multiple copies of the apparatus 300). Singulating the standalone package wafer and/or panel may include dicing the individual packages 465 from the standalone package wafer and/or panel. In some implementations, dicing the individual packages 465 from the standalone package wafer and/or panel may include laminating dicing tape onto the standalone package wafer and/or panel, dicing the individual packages 465 from the standalone package wafer and/or panel, and/or cleaning residual dicing tape and/or other contaminants from the diced packages 465.

As indicated above, FIGS. 4A-4D are provided as an example. Other examples may differ from what is described with regard to FIGS. 4A-4D.

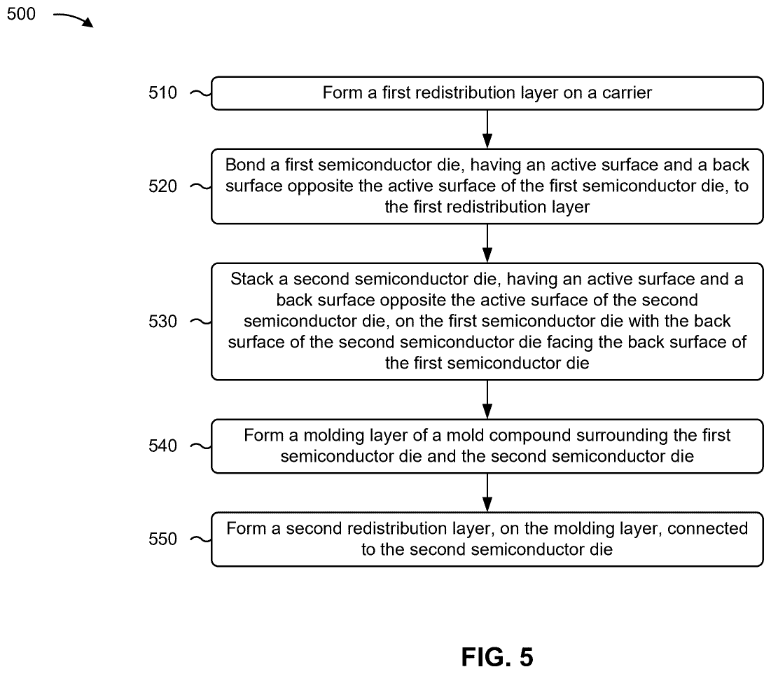

FIG. 5 is a flowchart of an example method 500 of forming an integrated assembly or memory device having a package with back-to-back die stacking. In some implementations, one or more process blocks of FIG. 5 may be performed by various semiconductor manufacturing equipment.

As shown in FIG. 5, the method 500 may include forming a first redistribution layer on a carrier (block 510). As further shown in FIG. 5, the method 500 may include bonding a first semiconductor die, having an active surface and a back surface opposite the active surface of the first semiconductor die, to the first redistribution layer (block 520). As further shown in FIG. 5, the method 500 may include stacking a second semiconductor die, having an active surface and a back surface opposite the active surface of the second semiconductor die, on the first semiconductor die with the back surface of the second semiconductor die facing the back surface of the first semiconductor die (block 530). As further shown in FIG. 5, the method 500 may include forming a molding layer of a mold compound surrounding the first semiconductor die and the second semiconductor die (block 540). As further shown in FIG. 5, the method 500 may include forming a second redistribution layer, on the molding layer, connected to the second semiconductor die (block 550).

The method 500 may include additional implementations, such as any single implementation or any combination of implementations described below and/or in connection with one or more other methods described elsewhere herein.

In a first implementation, forming the molding layer includes compressing the mold compound on the first semiconductor die, the second semiconductor die, and the first redistribution layer.

In a second implementation, alone or in combination with the first implementation, the method 500 includes forming one or more through-mold interconnects electrically connecting the first redistribution layer and the second redistribution layer.

In a third implementation, alone or in combination with one or more of the first and second implementations, forming the one or more through-mold interconnects is performed prior to forming the molding layer, and forming the molding layer includes surrounding the one or more through-mold interconnects with the mold compound.

In a fourth implementation, alone or in combination with one or more of the first through third implementations, forming the one or more through-mold interconnects is associated with at least one of vertical wire bonding or metal pillar plating.

In a fifth implementation, alone or in combination with one or more of the first through fourth implementations, forming the first redistribution layer on the carrier includes forming the first redistribution layer on a sacrificial layer disposed on the carrier.

In a sixth implementation, alone or in combination with one or more of the first through fifth implementations, the method 500 includes removing the carrier and the sacrificial layer, and applying a plurality of solder balls to the second redistribution layer.

In a seventh implementation, alone or in combination with one or more of the first through sixth implementations, bonding the first semiconductor die includes performing at least one of a reflow process or a thermal compression bonding process.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the structure 300 or 465, an integrated assembly that includes the structure 300 or 465, any part described herein of the structure 300 or 465, and/or any part described herein of an integrated assembly that includes the structure 300 or 465. For example, the method 500 may include forming one or more of the parts 302-324 and/or 402-424.

In some implementations, a semiconductor device assembly includes a first redistribution layer and a second redistribution layer; a first semiconductor die disposed between the first redistribution layer and the second redistribution layer, and connected to the first redistribution layer, the first semiconductor die having an active surface and a back surface opposite the active surface of the first semiconductor die; and a second semiconductor die disposed between the first redistribution layer and the second redistribution layer, and connected to the second redistribution layer, the second semiconductor die having an active surface and a back surface opposite the active surface of the second semiconductor die, and the second semiconductor die stacked on the first semiconductor die with the back surface of the second semiconductor die facing the back surface of the first semiconductor die.

In some implementations, a memory device includes a first redistribution layer and a second redistribution layer separated by a molding layer; a first memory die disposed in the molding layer between the first redistribution layer and the second redistribution layer; and a second memory die disposed in the molding layer between the first redistribution layer and the second redistribution layer, the first memory die and the second memory die stacked back-to-back.

In some implementations, a method includes forming a first redistribution layer on a carrier; bonding a first semiconductor die, having an active surface and a back surface opposite the active surface of the first semiconductor die, to the first redistribution layer; stacking a second semiconductor die, having an active surface and a back surface opposite the active surface of the second semiconductor die, on the first semiconductor die with the back surface of the second semiconductor die facing the back surface of the first semiconductor die; forming a molding layer of a mold compound surrounding the first semiconductor die and the second semiconductor die; and forming a second redistribution layer, on the molding layer, connected to the second semiconductor die.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a first redistribution layer and a second redistribution layer;
a first semiconductor die disposed between the first redistribution layer and the second redistribution layer, and connected to the first redistribution layer,
the first semiconductor die having an active surface and a back surface opposite the active surface of the first semiconductor die; and
a second semiconductor die disposed between the first redistribution layer and the second redistribution layer, and connected to the second redistribution layer,
the second semiconductor die having an active surface and a back surface opposite the active surface of the second semiconductor die, and
the second semiconductor die stacked on the first semiconductor die with the back surface of the second semiconductor die facing the back surface of the first semiconductor die.

2. The semiconductor device assembly of claim 1, wherein the active surface of the first semiconductor die faces the first redistribution layer, and the active surface of the second semiconductor die faces the second redistribution layer.

3. The semiconductor device assembly of claim 1, wherein the first semiconductor die and the second semiconductor die are vertically symmetrical.

4. The semiconductor device assembly of claim 1, wherein the first semiconductor die and the second semiconductor die define a first back-to-back die stack, and
wherein the semiconductor device assembly further comprises a second back-to-back die stack disposed between the first redistribution layer and the second redistribution layer.

5. The semiconductor device assembly of claim 1, wherein the active surface of the first semiconductor die has one or more interconnects that connect to electrical connections of the first redistribution layer via solder joints.

6. The semiconductor device assembly of claim 1, wherein the active surface of the second semiconductor die has one or more interconnects that directly connect to electrical connections of the second redistribution layer free of solder joints.

7. The semiconductor device assembly of claim 1, further comprising:
a mold compound between the first redistribution layer and the second redistribution layer, and surrounding the first semiconductor die and the second semiconductor die.

8. The semiconductor device assembly of claim 1, wherein the first semiconductor die and the second semiconductor die are dynamic random access memory (DRAM) integrated circuit dies.

9. The semiconductor device assembly of claim 1, further comprising:
a die attach film between the first semiconductor die and the second semiconductor die.

10. A memory device, comprising:
a first redistribution layer and a second redistribution layer separated by a molding layer;
a first memory die disposed in the molding layer between the first redistribution layer and the second redistribution layer; and
a second memory die disposed in the molding layer between the first redistribution layer and the second redistribution layer,
the first memory die and the second memory die stacked back-to-back.

11. The memory device of claim 10, wherein an active surface of the first memory die faces the first redistribution layer, and an active surface of the second memory die faces the second redistribution layer.

12. The memory device of claim 10, wherein the first memory die is connected to the first redistribution layer, and the second memory die is connected to the second redistribution layer.

13. The memory device of claim 10, wherein the first memory die has one or more first interconnects that connect to electrical connections of the first redistribution layer via solder joints, and
wherein the second memory die has one or more second interconnects that directly connect to electrical connections of the second redistribution layer free of solder joints.

14. The memory device of claim 10, further comprising:
one or more through-mold interconnects electrically connecting the first redistribution layer to the second redistribution layer.

15. The memory device of claim 10, further comprising:
a plurality of solder balls electrically connected to the second redistribution layer.

16. A method, comprising:
forming a first redistribution layer on a carrier;
bonding a first semiconductor die, having an active surface and a back surface opposite the active surface of the first semiconductor die, to the first redistribution layer;
stacking a second semiconductor die, having an active surface and a back surface opposite the active surface of the second semiconductor die, on the first semiconductor die with the back surface of the second semiconductor die facing the back surface of the first semiconductor die;
forming a molding layer of a mold compound surrounding the first semiconductor die and the second semiconductor die; and
forming a second redistribution layer, on the molding layer, connected to the second semiconductor die.

17. The method of claim 16, further comprising forming one or more through-mold interconnects electrically connecting the first redistribution layer and the second redistribution layer.

18. The method of claim 16, wherein forming the first redistribution layer on the carrier includes forming the first redistribution layer on a sacrificial layer disposed on the carrier.

19. The method of claim 18, further comprising:
removing the carrier and the sacrificial layer, and
applying a plurality of solder balls to the second redistribution layer.

20. The method of claim 16, wherein bonding the first semiconductor die includes performing at least one of a reflow process or a thermal compression bonding process.
